(19) United States
(12) Patent Application Publication
(10) Pub. No.: US 2026/0070312 A1
(43) Pub. Date: Mar. 12, 2026

(54) DEFORMABLE STRUCTURES FORMED FROM METAL NANOPARTICLES AND USE THEREOF IN HEAT TRANSFER

(71) Applicant: Kuprion Inc., Waterbury, CT (US)

(72) Inventors: Alfred A. Zinn, Palo Alto, CA (US); Randall M. Stoltenberg, American Fork, UT (US); Samuel Stoltenberg, American Fork, UT (US); Nhi Ngo, San Jose, CA (US); Khanh Nguyen, San Jose, CA (US); Nicholas Antonopoulos, San Jose, CA (US); Nicholas Zinn, Palo Alto, CA (US)

(21) Appl. No.: 19/107,931

(22) PCT Filed: Oct. 11, 2023
(86) PCT No.: PCT/US2023/076581

§ 371 Date: Feb. 28, 2025

Related U.S. Application Data
(60) Provisional application No. 63/379,257, filed on Oct. 12, 2022.

(51) Int. Cl. B32B 15/04; B32B 3/26; B32B 5/18; B32B 7/08

(52) U.S. Cl. CPC B32B 15/046; B32B 3/263; B32B 5/18; B32B 7/08; B32B 2264/1055; B32B 2266/045; B32B 2307/7376; B32B 2581/00

(57) ABSTRACT

Deformable structures suitable for serving as a thermal gasket may comprise a deformable metal body having a uniform nanoporosity of about 40% to about 75% by volume, in which the deformable metal body is freestanding and formed from a plurality of metal nanoparticles that are partially consolidated together with each other. A thermal interface may be established by placing a thermal gasket defined by the deformable structures between a heat source and a heat sink. A pressurizing load may be established upon the thermal gasket, optionally by mechanically coupling the thermal gasket to a heat sink.

### BACKGROUND

Excess heat may be generated within a variety of systems. Removal of the excess heat may be needed to ensure effective operation takes place for a given system. Failure to remove excess heat from an electronic system can result in significant consequences such as, for example, overheating, reduced conduction, higher power requirements than normal, and/or the need for clock-down operation to avoid board burnout and device failure. In some instances, operational modifications may be employed to limit the production of excess heat, rather than altering a system architecture to promote better heat removal. Sub-optimal performance may occur, either as a result of poor heat removal or modified operating conditions.

As electronics continue to be miniaturized, while also increasing in function and capability, one limiting concern is heat generation that may diminish performance of high-density circuits unless effective heat dissipation takes place, such as through use of a thermal interface material (TIM). Ineffective thermal communication between a heat source and a heat sink can hamper dissipation of excess heat from a system. To improve thermal contact between a heat source and a heat sink, a thermal interface material may be employed to improve thermal conductivity between the heat source and the heat sink. The term “thermal interface material” can be used broadly to describe any material that is inserted between two parts to enhance thermal coupling by facilitating heat transfer therebetween.

Thermal greases are frequently used for the foregoing purpose, although their thermal conductivity may be less than desirable, certainly lower than that of a metal, and they can be messy to apply and difficult to maintain. For example, under sufficiently hot operating conditions, a thermal grease may decrease in viscosity and leach/flow from a desired location within a system, thereby lessening the extent of thermal communication taking place between a heat source and a heat sink. As a result, frequent thermal grease replacement may be needed, thereby leading to excessive system downtime and maintenance costs. In addition, because thermal greases do not cure, their use is limited to systems in which the viscosity of the thermal grease will allow it to remain in position during use.

Alternatives to thermal greases include thermal adhesives or glues, solder thermal insulating materials, thermal tapes, and thermally conductive pads, typically made mostly of silicone or silicone materials. Other alternatives to thermal greases include metallic thermal gaskets, which may provide a pathway having high thermal conductivity between a heat source and a heat sink. In addition to their high thermal conductivity, metallic thermal gaskets may be resistant to vibration and shock, thereby making them suitable for rugged operating environments. It may be difficult, however, for a metallic thermal gasket to conform to the surface profile of both a heat source and a heat sink, thereby lowering the thermal communication below a level that would otherwise be achieved.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and having the benefit of this disclosure.

FIGS. 1 and 2 are diagrams of presumed structures of metal nanoparticles having a surfactant coating thereon.

FIG. 3 is a diagram of an illustrative metal gasket, according to one or more embodiments of the present disclosure.

FIG. 4 is a diagram of an illustrative metal gasket mechanically coupled to a heat sink, according to one or more embodiments of the present disclosure.

FIG. 5 is a diagram of an illustrative metal gasket interposed between a heat source and heat sink, according to one or more embodiments of the present disclosure.

FIGS. 6 and 7 are SEM images of illustrative metal gaskets formed from consolidation of copper nanoparticles and having differing levels of porosity, according to one or more embodiments of the present disclosure.

### DETAILED DESCRIPTION

The present disclosure is generally directed to heat transfer and, more specifically, thermal interface materials located between a heat source and a heat sink.

As indicated above, ineffective heat transfer between a heat source and a heat sink may be problematic. Thermal greases can be messy and may afford lower thermal conductivity than desirable. Thermal gaskets may provide higher thermal conductivity, but it may be difficult to achieve sufficient conformance between the heat source and the heat sink for optimal heat transfer to be realized.

The present disclosure provides deformable structures that may serve as effective thermal gaskets when placed between a heat source and a heat sink. The terms “thermal gasket” and “metal gasket” may be used interchangeably herein. The deformable structures may be formed by partially consolidating metal nanoparticles together with one another to form a highly porous metal body, which may be further compacted when a pressurizing load (mechanical force) is applied thereto, such as when interposed between a heat source and a heat sink. Application of pressurizing load to the thermal gaskets may be further aided by an optional mechanical connector that secures the thermal gasket to the heat sink, which may be performed with equipment similar to that used in conjunction with conventional thermal gaskets for improving heat transfer. While mechanical coupling of metallic thermal gaskets to a heat sink is known, conventional thermal gaskets may remain incompletely conformed to the surface of the heat sink and/or the heat source even when mechanically coupled thereto. Without being bound by theory or mechanism, the lack of conformance is believed to arise from the tendency of metals to hold their shape under a modest mechanical load due to their relatively high stiffness, thus failing to fully assume the profile of a surface with which they are in contact. The present disclosure alleviates this difficulty and provides related advantages as well.

The heat sink and the heat source may be one in the electronics sector, in which the heat source may be an integrated circuit package. The thermal insulating material may be inserted between a heat source and a heat sink or heat spreader, such as between an integrated circuit package and a finned heat exchanger, to improve the transfer of heat from the heat source to the heat sink or heat spreader. The thermal gaskets described herein may be used for this purpose. Thermal interface materials (TIMs), including the thermal gaskets described herein, may also be used between a heat source and a heat sink in locations including, but not limited to, personal computers, server computers, memory modules, graphics chips, radar and radio-frequency (RF) devices, disc drives, displays, including light-emitting diode (LED) displays, lighting systems, automotive control units, power-electronics, solar cells, batteries, communications equipment, such as cellular phones, thermoelectric generators, and imaging equipment, such as MRIs. In another example, the thermal gaskets described herein may be utilized in an IC (integrated circuit) package to connect the top of a chip to a casing encapsulating the IC.

The present disclosure describes how metal nanoparticles may be utilized to form deformable structures that may serve as effective metal gaskets for heat transfer applications, as well as other situations in which metal deformation may be desirable. In particular, metal nanoparticles may form a highly porous bulk metal which may be readily deformable when placed under a pressurizing load, such as when interposed between a heat source and a heat sink. Metal nanoparticles are uniquely qualified to form metal gaskets and other metal bodies having a highly porous structure. As described in further detail below, metal nanoparticle compositions may be processed at relatively low temperatures (˜200° C.-260° C.) to form bulk metal. The conditions under which the metal nanoparticles undergo consolidation with one another, as well as combining other additives with the metal nanoparticles, may allow a tailored extent of porosity to be realized in bulk metal resulting therefrom. The porosity may encourage conformance to a heat source and a heat sink, as referenced above.

Copper may be a desirable metal to include in a thermal gasket due to its relatively low cost and high thermal conductivity. In addition to the advantages offered by elemental copper, copper nanoparticles may be synthesized in a tailored range of sizes and formulated into paste compositions that may be readily dispensed for fabrication into a thermal gasket according to the disclosure herein. Although copper may be a desirable metal in the foregoing, it is to be appreciated that other metals may be utilized in a similar manner.

Low-temperature consolidation (fusion) of metal nanoparticles, including copper nanoparticles, is made possible by the heightened activity of the metal nanoparticles compared to the corresponding bulk metal. As a result, metal nanoparticles may at least partially consolidate (fuse) together with one another at a temperature much lower than the metal's melting point to afford bulk metal within a structure. Once the metal nanoparticles have been at least partially fused together, properties similar to those of the corresponding bulk metal may be realized (e.g., high melting points and high thermal conductivity values), but the nanoparticle origin of the bulk metal may be distinguishable by a significant amount of grain boundaries and nanoporosity. When achieved according to the present disclosure, the nanoporosity may constitute up to about 75% or up to about 50% of the bulk metal by volume, such as about 30% to about 50% by volume, or about 40% to about 75% by volume, or about 50% to about 70% by volume, or about 60% to about 75% by volume in order to realize the benefits and features described herein, specifically to encourage formation of a metal body having sufficient deformability. Other applications producing bulk metal from metal nanoparticles may seek to maintain the nanoporosity at a considerably lower level to produce microstructures having a similar microstructure and density to that of bulk, cast metal.

Before further discussing the embodiments of the present disclosure in further detail, a brief description of metal nanoparticles and metal nanoparticle compositions suitable for use in the present disclosure will first be provided, with copper nanoparticles being a representative example of metal nanoparticles that may be present as a majority metal nanoparticle in the metal nanoparticle compositions. Metal nanoparticles exhibit a number of properties that can differ significantly from those of the corresponding bulk metal. One property of metal nanoparticles that can be of particular importance is nanoparticle fusion or consolidation that occurs at the metal nanoparticles'fusion temperature. As used herein, the term “fusion temperature” refers to the temperature at which a metal nanoparticle liquefies, thereby giving the appearance of melting. As used herein, the terms “fusion,” “sintering” and “consolidation” synonymously refer to the coalescence or partial coalescence of metal nanoparticles with one another to form a larger mass (sintered mass) of bulk metal, thereby defining a bulk metal matrix, such as bulk copper matrix. During nanoparticle fusion, the metal nanoparticles undergo consolidation to form the bulk metal matrix without proceeding through a liquid state.

Upon decreasing in size, particularly below about 200 nm in equivalent spherical diameter, the temperature at which metal nanoparticles coalesce drops dramatically from that of the corresponding bulk metal. For example, copper nanoparticles having a size of about 150 nm or less can have fusion temperatures of about 240° C. or below, or about 220° C. or below, or about 200° C. or below, in comparison to bulk copper's melting point of 1084° C. Some of the metal nanoparticles may be about 20 nm or less in size, which may have especially low fusion temperatures and promote consolidation of larger metal nanoparticles. Thus, the consolidation of metal nanoparticles taking place at the fusion temperature can allow objects containing a bulk metal matrix to be fabricated at significantly lower processing temperatures than when working directly with the bulk metal itself as a starting material. Once the bulk metal matrix has been formed, the melting point of the bulk metal matrix may resemble that of the bulk metal itself and the bulk metal matrix may contain a plurality of grain boundaries. Optionally, indium or gallium may be included to promote consolidation and lessen the extent of grain boundaries that are present.

As used herein, the term “metal nanoparticle” refers to metal particles that are about 350 nm or less in size or about 200 nm or less in size, without particular reference to the shape of the metal particles. Mixtures of metal nanoparticles less than 200 nm in size in combination with metal nanoparticles between 200 nm and 350 nm in size may be used in some cases. As used herein, the term “copper nanoparticle” refers to a metal nanoparticle made from copper or predominantly copper.

As used herein, the term “micron-size metal particles” refers to metal particles that are about 400 nm or greater in size or about 500 nm or greater in size in at least one dimension, without particular reference to the shape of the metal particles.

The terms “consolidate,” “consolidation” and other variants thereof are used interchangeably herein with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain essentially none of the structural morphology of the original unfused metal nanoparticles (i.e., they resemble bulk metal with minimal grain boundaries), partially fused metal nanoparticles retain at least some of the structural morphology of the original unfused metal nanoparticles. The properties of partially fused metal nanoparticles can be intermediate between those of the corresponding bulk metal and the original unfused metal nanoparticles. Moreover, partial fusion may afford a metal structure having considerably higher nanoporosity.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a paste composition, if desired.

Any suitable technique can be employed for forming the metal nanoparticles used in the metal nanoparticle compositions and processes described herein. Particularly facile metal nanoparticle fabrication techniques are described in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Further description of suitable surfactant systems follows below. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N, N-dimethylformamide, dimethyl sulfoxide, dimethylpropylene urea, hexamethylphosphoramide, tetrahydrofuran, and glyme, diglyme, triglyme, and tetraglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

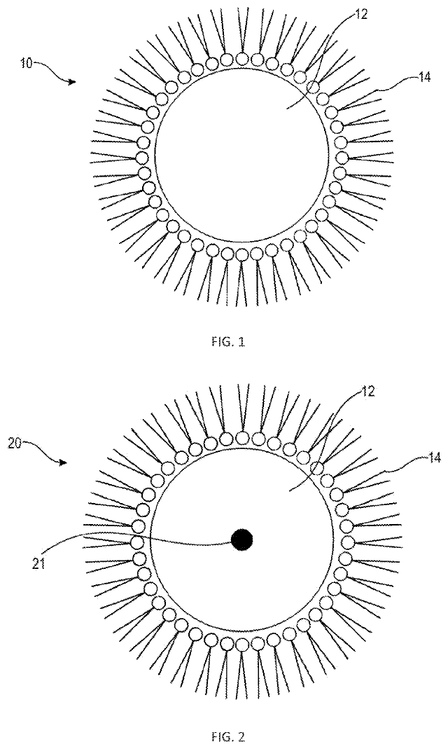

FIGS. 1 and 2 show diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20, it is not believed to significantly affect the overall nanoparticle properties. In some embodiments, nucleus 21 may comprise a substance that is a grain growth inhibitor, which may be released as the metal nanoparticles undergo consolidation with one another. In some embodiments, the nanoparticles can have an amorphous morphology.

As discussed above, the metal nanoparticles have a surfactant coating containing one or more surfactants upon their surface. The surfactant coating can be formed on the metal nanoparticles during their synthesis. The surfactant coating is generally lost during consolidation of the metal nanoparticles upon heating above the fusion temperature. Formation of a surfactant coating upon metal nanoparticles during their syntheses can desirably limit the ability of the metal nanoparticles to fuse to one another before heating above the fusion temperature, limit agglomeration of the metal nanoparticles, and promote the formation of a population of metal nanoparticles having a narrow size distribution.

Copper can be a particularly desirable metal in the embodiments of the present disclosure due to its low cost, strength, and excellent electrical and thermal conductivity values, as well as additional advantages addressed further herein. Although copper nanoparticles may be advantageous for use in the disclosure herein, it is to be appreciated that other types of metal nanoparticles may be used in alternative embodiments. Other metal nanoparticles that may be useful in electronic applications for forming a bulk metal matrix include, for example, aluminum nanoparticles, palladium nanoparticles, silver nanoparticles, gold nanoparticles, iron nanoparticles, cobalt nanoparticles, nickel nanoparticles, titanium nanoparticles, zirconium nanoparticles, hafnium nanoparticles, tantalum nanoparticles, and the like.

In various embodiments, the surfactant system present within the metal nanoparticles can include one or more surfactants. The differing properties of various surfactants can be used to tailor the properties of the metal nanoparticles and the porosity resulting following consolidation thereof. Factors that can be taken into account when selecting a surfactant or combination of surfactants for inclusion upon the metal nanoparticles can include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent. Further disclosure regarding suitable amine surfactants follows hereinafter.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁₂ range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N,N′-dialkylethylenediamines, particularly C₁-C₄ N, N′-dialkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N, N′-di-t-butylethylenediamine, N,N′-diisopropylethylenediamine, and the like.

In some embodiments, suitable diamine chelating agents can include N,N,N′,N′-tetraalkylethylenediamines, particularly C₁-C₄ N,N,N′,N′-tetraalkylethylenediamines. The corresponding methylenediamine, propylenediamine, butylenediamine, pentylenediamine or hexylenediamine derivatives can also be used. The alkyl groups can again be the same or different and include those mentioned above. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present. Further disclosure regarding suitable pyridines, aromatic amines, phosphines, and thiols follows below.

Suitable aromatic amines can have a formula of ArNR¹R², where Ar is a substituted or unsubstituted aryl group and R¹ and R² are the same or different. R¹ and R² can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphophine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bis-phosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

The metal nanoparticles described hereinabove can be incorporated within various metal nanoparticle compositions, which may facilitate dispensation into a deformable metal structure, which may be a self-supporting (freestanding) form, such as a foil, foam, or film in the disclosure herein. Illustrative disclosure directed to such metal nanoparticle compositions follows hereinafter, with copper nanoparticles being an illustrative type of metal nanoparticles that may be used in the metal nanoparticle compositions and used to form a deformable structure.

Metal nanoparticle compositions can be prepared by dispersing as-produced or as-isolated metal nanoparticles in an organic matrix containing one or more organic solvents and various other optional components. As used herein, the terms “nanoparticle paste formulation” and “nanoparticle paste composition” may be used interchangeably with “metal nanoparticle composition” and refer synonymously to a fluid composition containing dispersed metal nanoparticles that is suitable for dispensation using a desired technique. The viscosity may vary over a wide range depending on the chosen dispensation technique. Use of the term “paste” does not necessarily imply an adhesive function of the paste alone. Through judicious choice of the organic solvent(s) and other additives, the loading of metal nanoparticles and the like, dispensation of the metal nanoparticles in a desired location may be promoted and the properties of a metal matrix (layer) resulting therefrom may be tailored. In particular, the porosity of a metal body may be tailored by altering the content of the metal nanoparticle composition and the rate at which the metal nanoparticles (e.g., copper nanoparticles) undergo consolidation with one another and the extent to which consolidation takes place.

Tailoring of the porosity of a metal body resulting from consolidation of metal nanoparticles within a metal nanoparticle composition may be realized in a variety of ways. In some instances, metal nanoparticle fusion and a high degree of consolidation may be realized by tailoring the boiling point range of the organic solvents present in a metal nanoparticle paste composition, such that the paste stays wet until a peak fusion temperature is reached. The foregoing may be accomplished by stepping the boiling point range up gradually by choice of various paste components (organic solvents) having a range of ever-increasing boiling points and matching the paste boiling point range with a desired fusion profile and peak fusion temperature of the metal nanoparticles. To increase the resulting porosity, the boiling point range of the metal nanoparticle paste may also be decreased, thereby resulting in a lower average boiling point range and slowing down the fusion profile somewhat to give the metal nanoparticles time to fuse together without undergoing significant consolidation to decrease porosity, which may lead to a more compressible and open porous network. A somewhat lower peak fusion temperature may also aid in this process.

In conventional metal nanoparticle consolidation processes producing relatively dense consolidated metal matrices, an average boiling point range of about 230° C. to about 300° C. or about 350° C. for a paste composition may be used in combination with a 230° C. to 240° C. peak fusion temperature. In non-limiting examples, to achieve a higher porosity in the disclosure herein, an average boiling point range of about 150° C. to about 220° C. for a paste composition may be used in combination with a peak fusion temperature of about 180° C. to about 230° C.

In addition, metal nanoparticle paste compositions having a decreased average boiling point range and a lower peak fusion temperature may undergo consolidation with staged heating that gradually ramps the processing temperature up to the peak fusion temperature. Metal nanoparticle consolidation may take place while transporting a dispensed paste through an oven having multiple temperature zones. For example, a four-stage conveyer belt system may transport a metal nanoparticle paste through a first zone having a temperature of about 40° C. to about 75° C. or about 50° C. to about 60° C., a second zone having a temperature of about 100° C. to about 190° C. or about 120° C. to about 140° C., a third zone having a temperature of about 180° C. to about 220° C. (e.g., about 180° C.), and a fourth zone having a temperature of about 200° C. to about 240° C. (e.g., about 220° C.). The transit time through the first two zones may be longer than through the last two zones (e.g., 80-90 seconds for the first two zones and about 20-50 seconds for the last two zones). The substrate on which consolidation takes place, specifically the thermal conductivity thereof, may further impact the resulting porosity. For materials having a low thermal conductivity (e.g., about 1 to about 250 W·m/K) and/or a high heat capacity (e.g., ˜2-4 J·cm⁻³K⁻¹, such as a steel or copper plate (3.756 J·cm⁻³ K⁻¹ and 3.45 J·cm⁻³ K⁻¹, respectively), or a thicker plate (e.g., 2-5 mm) of either of these metals), heat transfer to the metal nanoparticle paste may be slower and the resulting porosity may increase. In contrast, if the substrate has a high thermal conductivity (e.g., greater than about 200 W·m/K or greater than 250 W·m/K), a low heat capacity (e.g., less than 2 J·cm⁻³ K⁻¹) and/or is relatively thin (e.g., 300-1000 microns), heat transfer may be rapid and a denser material may be obtained. For example, in the latter case, heat transfer coefficients may be about 750 W/cm²·K or above.

As still another option to control the resulting porosity, grain growth inhibitors may be included in the metal nanoparticle paste. Suitable grain growth inhibitors may accumulate at the grain boundaries to pin the grain boundaries in place and slow down grain growth. Such slowing of grain growth may similarly increase the porosity. In non-limiting examples, suitable grain growth inhibitors may include metal oxides, such as oxides of Ti, Zr, Hf, Cu, Mg, or the like. Other grain growth inhibitors may also be suitable, as discussed further below.

A lower solids content in the metal nanoparticle paste may likewise increase porosity upon consolidation. Specifically, volatile additives may replace metal nanoparticles in the paste compositions to lower the solids content. Volatile additives may take up space between the metal nanoparticles and leave void space behind as they boil away. The void space may prevent complete consolidation from taking place. Although a lower solids content may help promote a higher extent of porosity, if the solids content is too low, excessive cracking may result, as explained further below. A usual solution for limiting cracking upon metal nanoparticle consolidation is to include micron-size metal particles in a metal nanoparticle paste; however, inclusion of an excessive amount of micron-size metal particles in a metal nanoparticle paste configured for producing high porosity may limit compressibility following consolidation. Accordingly, metal nanoparticle paste compositions used in the disclosure herein may be desirably free of micron-size metal particles that are larger than the metal nanoparticles. For example, micron-size metal particles larger than about 400 microns may be absent from the metal nanoparticle paste compositions disclosed herein.

The metal nanoparticle paste compositions may have a solids content that suitably balances cracking and shrinkage against production of a desired degree of porosity. To achieve a sufficient degree of porosity, the metal nanoparticle paste compositions may have a solids content of about 65% or below on a volume basis. In some embodiments, the metal nanoparticle compositions can contain about 15% to about 60% metal nanoparticles by volume, such as about 15% to about 40% metal nanoparticles by volume of the composition, or about 30% to about 50% metal nanoparticles by volume of the composition, or about 40% to about 65% metal nanoparticles by volume of the composition. Preferably, micron-scale metal particles may be omitted from the compositions having such relatively low overall solids content.

Following consolidation, a copper matrix (or alternative metal matrix) resulting from fused copper nanoparticles may be characterized by a very fine, uniformly distributed nanoporosity. For many conventional applications seeking a relatively dense metal matrix, a low nanoporosity of about 4-15% may be desirable, which may promote more uniform heat distribution across a surface and better mechanical properties, for example. In the deformable metal structures and thermal gaskets disclosed herein, much higher nanoporosity values in the 30-50%, or 40-75%, or 50-70% range by volume may be more desirable, wherein the additional porosity may promote deformation and flexibility to the bulk copper or other type of deformable metal body. The nanoporosity may exhibit a pore size in the range of about 100 nm to about 300 nm or about 300 nm to about 3000 nm, with only moderate pore interconnectivity at lower porosity values below about 30% (i.e., predominantly closed pores are present). At intermediate porosity values, a mixture of open and closed cells may be present. Above about 50% porosity, the pores may be predominantly interconnected and resemble an open-cell metal foam. That is, above about 50% porosity (e.g., in a range of about 50% to about 75% by volume or about 60% to about 75% by volume), at least a majority of the nanoporosity may comprise a plurality of open cells. Nanoporosity values in the foregoing range may be achieved with metal nanoparticle paste compositions formulated according to the disclosure herein.

In addition to aiding in formation of a desired degree of porosity, the solvent(s) in the organic matrix may also promote decreased cracking during consolidation as well. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition to promote porosity can be performed to increase the suddenness of volume contraction that takes place during surfactant removal and metal nanoparticle consolidation. Increasing the suddenness of volume contraction may favor formation of increased porosity. Specifically, more than one member of each class of organic solvent (i.e., hydrocarbons, alcohols, amines, and organic acids), can be present in the organic matrix, where the members of each class have boiling points that are separated from one another by a set degree. For example, in some embodiments, the various members of each class can have boiling points that are separated from one another by less than about 1° C. or less than about 5° C., such as between about 0° C. to about 10° C. or about 15° C. to about 30° C. By using such a solvent mixture, the volume change may occur suddenly due to rapid loss of solvent in a narrow temperature window, thereby reducing densification during metal nanoparticle fusion. When the volume change is rapid over a narrow boiling point range (e.g., about 50° C. to about 200° C.) the solids cannot follow the sudden change, thereby leading to a more porous structure. When consolidating metal nanoparticle compositions to produce a denser metal matrix, in contrast, increasing the boiling point spread may be more desirable.

In some embodiments, the one or more organic solvents may have a boiling point of about 50° C. to about 250° C., or about 50° C. to about 150° C., or about 100° C. to about 200° C. Preferably, the one or more organic solvents may have a boiling point that is lower than the boiling point(s) of the surfactant(s) associated with the metal nanoparticles. Accordingly, organic solvent(s) can be removed from the metal nanoparticles by evaporation before or concurrently with removal of the surfactant(s) taking place at or above the peak fusion temperature.

In some embodiments, the organic matrix can contain one or more alcohols. In various embodiments, the alcohols can include monohydric alcohols, diols, triols, glycol ethers (e.g., diethylene glycol and triethylene glycol), alkanolamines (e.g., ethanolamine, triethanolamine, and the like), or any combination thereof. In some embodiments, one or more hydrocarbons can be present in combination with one or more alcohols. As discussed above, it is believed that alcohol and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C₁₀-C₁₃ alkanes), diisopropyleneglycol monomethyl ether, diethyleneglycol diethyl ether, 2-propanol, 2-butanol, t-butanol, 1-hexanol, 2-(2-butoxyethoxy)ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As discussed above, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow)amine (CAS 61789-79-5), dialkyl (C₈-C₂₀) amines (CAS 68526-63-6), alkyl (C₁₀-C₁₆)dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, a-linolenic acid, stearidonic acid, oleic acid, and linoleic acid.

In some embodiments, the organic matrix can include more than one hydrocarbon, more than one alcohol, more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described hereinafter.

One particular advantage of using multiple members within each class of organic solvent can include the ability to tailor boiling points in the nanoparticle paste compositions over a fairly narrow range. By providing a narrow spread of boiling points, the organic solvents can be removed rapidly as the temperature rises to promote a high degree of porosity and incomplete densification during metal nanoparticle consolidation. By rapidly removing the organic solvent in this manner and using lower temperatures to promote organic solvent removal, faster metal nanoparticle consolidation with incomplete densification may be realized in comparison to using a single solvent or multiple solvents having a broader boiling point range spread. Less temperature control may be needed to affect slow solvent removal than if a single solvent with a narrow boiling point range was used. In some embodiments, the members within each class of organic solvent can have a window of boiling points ranging between about 50° C. and about 150° C., or between about 50° C. and about 200° C., or between about 100° C. and about 200° C., or between about 100° C. and about 250° C. In more particular embodiments, the various members of each class of organic solvent can each have boiling points that are separated from one another by about 1° C. or less, or about 5° C. or less, or about 10° C. or less, or about 20° C. or less, such as about 5° C. to about 10° C. or about 5° C. to about 15° C., or about 10° C. to about 20° C. More specifically, in some embodiments, each hydrocarbon can have a boiling point that differs by about 1° C. or less, or about 5° C. or less, or about 10° C. or less or about 20° C. or less from other hydrocarbons in the organic matrix, each alcohol can have a boiling point that differs by about 1° C. or less, or about 5° C. or less, or about 10° C. or less, or about 20° C. or less from other alcohols in the organic matrix, each amine can have a boiling point that differs by about 1° C. or less, or about 5° C. or less, or about 10° C. or less or about 20° C. or less from other amines in the organic matrix, and each organic acid can have a boiling point that differs by about 1° C. or less, or about 5° C. or less, or about 10° C. or less or about 20° C. or less from other organic acids in the organic matrix. In some embodiments, each class organic solvent within the organic matrix can have boiling points that are separated from one another by about 1° C. or less, or about 5° C. or less, or about 10° C. or less, or about 20° C. or less, such as about 5° C. to about 10° C. or about 5° C. to about 15° C., or about 10° C. to about 20° C. By maintaining the small boiling point differences, the suddenness of volume contraction may increase and promote a high degree of porosity in the disclosure herein.

In some embodiments, at least a portion of the metal nanoparticles present in the nanoparticle paste compositions can be about 20 nm or less in size. Such metal nanoparticles may be characterized by their relatively low fusion temperatures and formation of relatively dense metal matrices. However, to lessen the extent of consolidation for purposes of increasing porosity, it can be desirable for the metal nanoparticle paste compositions to contain at least some larger metal nanoparticles, such as about 25 nm or more in size. In some embodiments, at least a portion of the metal nanoparticles may be about 75 nm or larger in size, or about 100 nm or larger in size, or about 150 nm or larger in size, or even up to about 350 nm in size, such as about 200 nm to about 300 nm in size, or about 250 nm to about 350 nm in size. More preferably, all of the metal nanoparticles in the metal nanoparticle paste compositions may be about 25 nm or larger in size, or about 75 nm or larger in size, or about 100 nm or larger in size, or about 150 nm or larger in size, or even up to about 350 nm in size, such as about 200 nm to about 300 nm in size, or about 250 nm to about 350 nm in size. Metal nanoparticles in the foregoing size ranges may exhibit fusion temperatures that are higher than those of metal nanoparticles below about 20 nm in size, but still below the melting point of the corresponding bulk metal. Thus, these larger metal nanoparticles may still undergo ready consolidation with each other at relatively low processing temperatures. Combinations of metal nanoparticles in two or more non-overlapping size ranges above about 25 nm may also be utilized to promote tailoring of the porosity resulting from metal nanoparticle consolidation. Spherical or substantially spherical nanoparticles may be preferred in the disclosure herein, with less than about 15% platelets or flakes by mass being present.

In some embodiments, at least a portion of the metal nanoparticles may range from about 15 nm in size to about 65 nm in size, or from about 25 nm in size to about 100 nm in size, or from about 35 nm in size to about 150 nm in size, or from about 50 nm in size to about 200 nm in size, or from about 75 nm in size to about 250 nm in size. Any of the foregoing size ranges may be combined with metal nanoparticles that are about 250 nm to about 350 nm in size, which may afford a bimodal size distribution in some cases. In some embodiments, larger metal nanoparticles can be combined in the metal nanoparticle compositions with metal nanoparticles that are about 25 nm in size or less. In other embodiments, smaller metal nanoparticles need not necessarily be present, and the metal nanoparticles may be about 30 nm or larger in size, or about 50 nm or larger in size, or about 75 nm or larger in size, or about 100 nm or larger in size, or about 150 nm or larger in size, such as within a size range of about 30 nm to about 200 nm, or about 75 nm to about 250 nm, or about 125 nm to about 350 nm.

In addition to metal nanoparticles and organic solvents, other additives can also be present in the nanoparticle paste compositions. Such additional additives can include, for example, rheology control aids, thickening agents, some micron-size conductive additives, nanoscale conductive additives, CTE modifiers, and any combination thereof. Chemical additives can also be present. The additional additives may be included in various amounts and combinations to alter the viscosity properties of the metal nanoparticle compositions to support dispensation of the metal nanoparticle compositions in a given location and by a specified technique. The additional additives may also be selected to maintain the ability of the metal nanoparticle compositions to form a highly porous metal matrix following consolidation of the metal nanoparticles therein.

Suitable nanoscale conductive additives can include, for example, carbon nanotubes, graphene, other graphite-type materials, and the like. When present, the metal nanoparticle compositions can contain about 1% to about 16% nanoscale conductive additives by weight, or about 1% to about 10% nanoscale additives by weight, or about 1% to about 5% nanoscale conductive additives by weight. Fine graphite powder may also be suitably present in the metal nanoparticle paste compositions as a solid lubricant. For graphite, a suitable size range may include about 100 nm to about 3 microns, whereas graphene and carbon nanotubes may naturally have at least one dimension in the nanometer size range. Suitable carbon nanotubes can be single-or multi-walled, and graphene sheet may be single-layered or multi-layered. Suitable graphenes may be oxidized, functionalized, or any combination thereof.

Metal nanoparticle compositions suitable for use in the present disclosure can be formulated using any of the formulations described hereinabove, including those in which a grain growth inhibitor is further included, particularly a grain growth inhibitor comprising a metal. The grain growth inhibitor may be included in a suitable form such that the grain growth inhibitor is capable of entering grain boundaries following nanoparticle consolidation. If not included in a suitable form, ineffective grain growth inhibition may occur, even if the grain growth inhibitor otherwise comprises a substance that is capable of providing grain growth inhibition. As indicated above, inclusion of a grain growth inhibitor may be desirable to immobilize grain boundaries for affording increased porosity.

In particular embodiments, metal nanoparticle compositions suitable for use in the disclosure herein may comprise copper nanoparticles and a suitable amount of a grain growth inhibitor to prevent substantial grain growth upon heating a bulk copper matrix formed from the copper nanoparticles. The suitable amount of the grain growth inhibitor may range from about 0.01 wt. % to about 15 wt. % of the composition, according to various embodiments. Effective temperature ranges over which the grain growth inhibitor may inhibit grain growth are considered below.

Suitable grain growth inhibitors may be metal particles that are insoluble in a copper matrix. Suitable grain growth inhibitors may be foreign nanoparticles that are in the 25 nm and under size range or about 10 nm and under size range. Grain growth inhibitors comprising a metal, particularly metal nanoparticles having a size of about 25 nm or under or about 10 nm or under, may be particularly desirable for inclusion in a bulk copper matrix. The small nanoparticle size allows the grain growth inhibitors to access the grain boundaries readily. Inclusion of the grain growth inhibitors limits grain growth by interface or Zener pinning and ensures that the nano-grain structure is retained even after prolonged exposure to high temperatures, frequent temperature cycling and thermal shock. These actions may prevent further atom diffusion and reorganization.

Suitable metals for a grain growth inhibitor may include, for example, Fe, Mn, Cr, Co, Ru, Si, V, W, Nb, Ta, Y, Zr, Hf, Be, Tl, Rh, Ir, Ti, Mo, Re, Al, alloys thereof, or any combination thereof, particularly nanoparticles comprising one or more of these metals. Si is considered to be a metal for purposes of the present disclosure. The metal particles may be metal nanoparticles, according to various embodiments. Nanoparticles of these metals may be particularly suitable. Other suitable grain growth inhibitors may include, for example, carbides, nitrides, borides, silicides, oxides, or phosphides. Suitable borides may include, for example, Zr/Hf, V, or Nb/Ta. Similar metals may be appropriate for carbides, nitrides, silicides, oxides, and phosphides, although any of the metals above may be suitable. Other suitable phosphides may include covalent phosphides such as BP and SiP₂, transition metal phosphides such as Fe₃P, Fe₂P, Ni₂P, CrP, MnP, MoP and the like. Metal-rich phosphides such as these may be desirable due to their water insolubility, electrical conductivity, high melting points, thermal stability, hardness, and similar properties. Other suitable carbides may include covalent carbides such as BC (including BₓC_{y} non-stoichiometric carbides) and SiC, and transition metal carbides, which similarly exhibit high melting points, hardness, electrical conductivity, and similar properties. Graphene and other nanocarbon materials may also be effective grain growth inhibitors in some cases.

Suitable grain growth inhibitors may be included in copper nanoparticle paste compositions in an amount ranging between about 0.01 wt. % to about 15 wt. %, or about 0.01 wt. % to about 5 wt. %, or about 0.1 wt. % to about 10 wt. % with respect to the composition or in a bulk copper matrix resulting therefrom. In more particular embodiments, the grain growth inhibitors may be present in an amount ranging between about 0.01 wt. % and about 5 wt. %, or between about 0.1 wt. % and about 0.5 wt. %. Particular copper nanoparticle compositions may comprise up to about 5 wt. % Al, or about 0.01-5 wt. % Zr, or 0.01-5 wt. % Zr/Hf. Aluminum may be advantageous for forming insoluble binary phases like CuAl₂ or Cu₉Al₄. Al₂O₃, including nanoparticles thereof, may also be a suitable grain growth inhibitor and may also impart enhanced oxidation resistance.

The grain growth inhibitors may be in various forms when incorporated/combined with the copper nanoparticles. In some embodiments, the grain growth inhibitors may be nanoparticles themselves, particularly having a size of about 25 nm or less or about 10 nm or less. In other embodiments, the grain growth inhibitors may range between 10 nm and 100 nm in size or between about 25 nm and about 100 nm in size.

When incorporated as nanoparticles, reagents for forming the grain growth inhibitors may be mixed with the reagents for forming the copper nanoparticles (or other types of metal nanoparticles) and then they may undergo co-reduction to form the copper nanoparticles and the grain growth inhibitors simultaneously. Suitable reagents for forming the grain growth inhibitors may include, for example, metal nitrates, chloride, bromides or iodides. The grain growth inhibitors may also constitute nanoparticle seeds for the copper nanoparticles (or other metal nanoparticles), and then become incorporated within the resulting bulk copper matrix following copper nanoparticle fusion. Nanoparticle seeds suitable for becoming a grain growth inhibitor may be made separately and combined with the reagents for forming the copper nanoparticles, or such nanoparticle seeds may be formed concurrently with forming the copper nanoparticles. Carrier solvents may be used to disperse the reagents for forming the nanoparticle seeds/grain growth inhibitors before dispersal with the copper nanoparticles or precursors to the copper nanoparticles.

Alternately, preformed grain growth inhibitors may be mixed with preformed copper nanoparticles (or other metal nanoparticles), either before or after formulating the copper nanoparticles into a metal nanoparticle composition.

In still other alternative embodiments, a trialkylaluminum compound (e.g., trimethylaluminum) may be incorporated in the metal nanoparticle compositions. The trialkylaluminum may react during copper nanoparticle consolidation to release aluminum or an aluminum compound into the grain boundaries.

Still further alternately, salts that form the grain growth inhibitors following reduction may be mixed within the metal nanoparticle compositions and then undergo reduction to form the grain growth inhibitors during consolidation of the metal nanoparticles. Carrier solvents may be used to promote mixing with the metal nanoparticle compositions.

In still other embodiments, NaReO4 may be formulated into a grain growth inhibitor. This salt is compatible with both aqueous and non-aqueous solvent conditions (including glyme solvent mixtures) and the same amines that may be used in forming copper nanoparticles. Reducing agents such as NaBH₄, CaH₂, hydrazine, organomagnesium or organosodium compounds, or redAl may be used to affect reduction.

Accordingly, the present disclosure provides deformable structures comprising a deformable metal body having a uniform nanoporosity of about 30% to about 50%, or about 40% to about 75%, or about 50% to about 70% by volume, in which the deformable metal body is freestanding and formed from a plurality of metal nanoparticles that are partially consolidated together with each other. In particular embodiments, the deformable metal body may comprise copper and be formed from a plurality of copper nanoparticles. Other types of metal nanoparticles that may be suitable are also provided above. The deformable structures may define a thermal gasket suitable for placement between a heat source and a heat sink in particular embodiments of the disclosure herein.

The deformable metal body may be freestanding, meaning that it may be formed and then freely manipulated before being deployed in a desired location, such as a thermal interface material (i.e., a thermal gasket) between a heat source and heat sink. In some embodiments, the deformable metal body may comprise a metal film, a metal foam, or a metal foil, which may be formed initially on a work surface (substrate) or within a mold and then undergo removal therefrom. Such metal films, metal foams, and metal foils may exhibit a substantially uniform through-plane thickness. The metal film, metal foam, or metal foil may have a thickness ranging from about 10 microns to about 1,000 microns or about 25 microns to about 500 microns or about 25 microns to about 100 microns.

In other embodiments, the deformable metal body may have a non-uniform thickness, and in some embodiments, at least one face of the deformable metal body may be contoured and/or have curvature to produce the non-uniform thickness. For example, at least one face of the deformable metal structure may be dome-shaped, for reasons discussed in further detail below. Likewise, the deformable metal body may include at least one face that is substantially flat (planar) and at least one face that is contoured and/or has curvature. Like metal films and foils, deformable metal bodies having a non-uniform thickness may have a maximum thickness at a geometric center thereof ranging from about 25 microns to about 50 microns, or about 25 microns to about 500 microns, or even up to about 1,000 microns in thickness. Away from the geometric center, the through-plane thickness of the deformable metal bodies may be less than the maximum thickness. For example, away from the geometric center and near the corners, the deformable metal body may have a thickness of at least about 10 microns and up to about 100 microns or in the range of about 15 to about 50 microns. When a deformable metal body is shaped in this manner, compaction of the deformable metal body as a function of applied pressure may encourage conformance to a surface, for example. Following compaction between a heat source and a heat sink, the pores may at least partially collapse to promote surface conformance. After compaction, the deformable metal body may be at least partially conformal with the surfaces of a heat source and a heat sink.

In non-limiting examples, the deformable metal body may have a radius of curvature along the contoured face thereof ranging from about 1 m to about 100 m, or about 5 m to about 50 m. For example, in the case of a rectangular 2 inch×3 inch (5.08 cm×7.62 cm) deformable metal body having a 10 micron thickness at the corners, a 25 micron thickness at the centers of each edge of the contoured face, and a 50 micron thickness at the center of the contoured face, the radius of curvature may be about 31 m along the shorter edge and about 47 m along the longer edge. The radius of curvature through the center of the deformable metal body and bisecting the shorter and longer edges may be about 17 m and about 7.8 m, respectively.

In non-limiting examples, the deformable metal body may have a ratio of surface area of the contoured face to thickness ranging from about 500 to about 5,000, or about 1,000 to about 10,000, or about 3,000 to about 8,000, or about 10,000 to about 60,000, or about 20,000 to about 50,000. For example, in the case of a rectangular 2 inch×3 inch (5.08 cm×7.62 cm) deformable metal body having a 50-100 micron thickness at the center of the contoured face, the ratio of surface area to thickness at the center of the contoured face may range from about 3,000 to about 8,000.

In some embodiments, the deformable metal body may be placed between a heat source and a heat sink in a semiconductor manufacturing process, such as in an integrated circuit assembly.

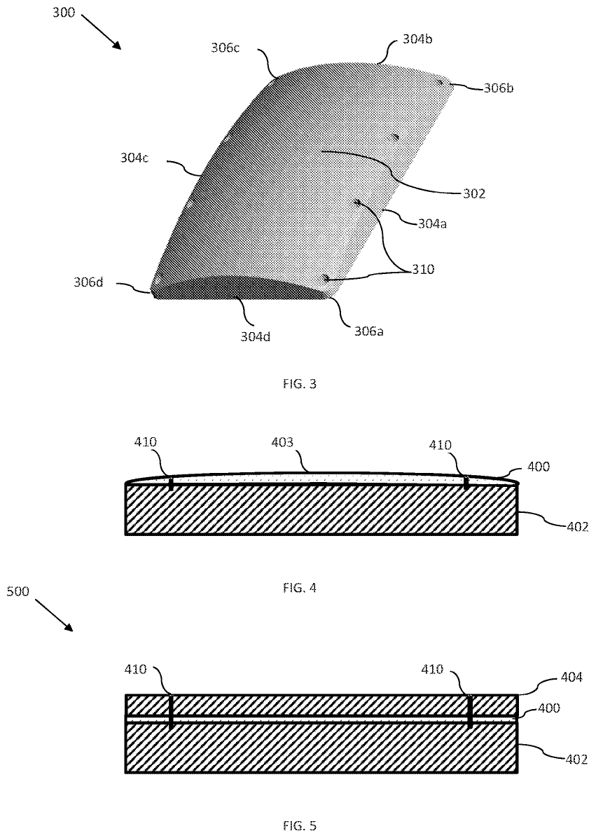

FIG. 3 shows a diagram of an illustrative thermal gasket having a contoured surface, according to one or more embodiments of the present disclosure. As shown, thermal gasket 300 includes contoured face 302, which has a maximum thickness along edges 304a-304d (e.g., at or near the midpoint thereof) or in a geometric center of contoured face 302 and a decreased thickness approaching corners 306a-306d.

In some embodiments, thermal gasket 300 also includes a plurality of holes 310 that may be utilized for mechanically coupling a substantially flat face (not apparent in the view of FIG. 3) of thermal gasket 300 to a heat sink. Suitable mechanical connectors may include, for example, spring-loaded push pins, captive screws or bolts, low-profile screws or bolts, or any combination thereof. Other types of mechanical connectors suitable for coupling a thermal gasket to a heat sink will be familiar to one having ordinary skill in the art. For example, generic screws, brads, push pins, nails, bolts, or the like may be utilized to affix a thermal gasket to a heat sink and to apply a pressurizing load to thermal gasket 300 to facilitate heat transfer between the heat source and the heat sink. Mechanical connectors may ensure a robust connection throughout the working lifetime of a thermal connection employing thermal gasket 300, although sufficient connectivity may be realized in some cases simply by having the heat source and the heat sink tightly pressed together. Thus, some embodiments of thermal gasket 300 may suitably omit mechanical connectors and holes 310.

Alternately, joining materials such as thermal adhesives, sinters, solders, tacking materials, and the like may be used to promote enhanced coupling of the thermal gasket to a heat sink. These joining materials may be applied as a thin layer across the surface of at least one of the thermal gasket or the heat sink or may be applied in discrete areas on a surface of at least one of the thermal gasket or the heat sink. Alternately, the joining materials may be incorporated into the porosity of the thermal gasket and squeeze out during pressure assembly to compress the thermal gasket between the heat source and the heat sink. Such joining materials may also be used in combination with the mechanical connectors described herein.

Alternately, compression pressure may be used to applying a pressurizing load to thermal gasket 300, including, for example, a compression pressure of at least about 25 psi or at least about 30 psi or at least about 50 psi to a maximum of about 100 psi. An initial assembly pressure of a higher value may be used during assembly for systems that can handle pressure beyond 100 psi. The compression pressure may be adjusted depending in part on the thickness of the thermal gasket, surface area of the thermal gasket, degree of contour of the thermal gasket, mechanical strength of the heat source or heat sink, and the like.

Alternately, a pressurizing load may be applied by mechanically coupling a heat source to a heat sink using similar types of mechanical connectors. In such embodiments, holes 310 may be omitted in thermal gasket 300, such that thermal gasket 300 is simply wedged or pressed between the heat source and the heat sink. As still another option, mechanical connectors or other joining materials may connect a heat source to a heat sink. For example, the mechanical connectors may simply pass through holes 310 in metal gasket 300 in order to hold metal gasket 300 in place while pressed between the heat source and the heat sink. Instead of passing through holes 310, mechanical connectors may be located outside the perimeter of metal gasket 300 to “fence in” and hold it in place. This configuration is often used in desktop computer components.

Upon being arranged between a heat source and a heat sink, with a pressurizing load applied thereto, the thermal gasket may collapse to a substantially planar (or quasi-two-dimensional form) to form a thermal interface conforming to a surface of both the heat source and the heat sink. The conversion of the thermal gasket from its originally contoured form to a planar or substantially planar form may be facilitated by the high nanoporosity utilized in the disclosure herein. Contoured face 302 of thermal gasket 300, when in a collapsed state, may experience a decrease in thickness in the range of about 10% to about 25%. The non-contoured portion of thermal gasket 300, when in a collapsed state, may experience a smaller decrease in thickness in the range of about 5% to about 10%. The amount of shrinkage/thickness decrease experienced by thermal gasket 300 may be a function of porosity; higher porosity may produce a greater thickness decrease and lower porosity may produce a smaller thickness decrease.

FIG. 4 shows a diagram of a thermal gasket mechanically coupled to a heat sink. As shown, thermal gasket 400 contacts heat sink 402 with a substantially planar face opposite contoured face 403. Mechanical connectors 410 extend through metal gasket 400 and at least partially into heat sink 402 to establish a mechanical connection therebetween. Once suitably connected, a heat source may be applied to contoured face 403, such that compaction of thermal gasket 400 occurs.

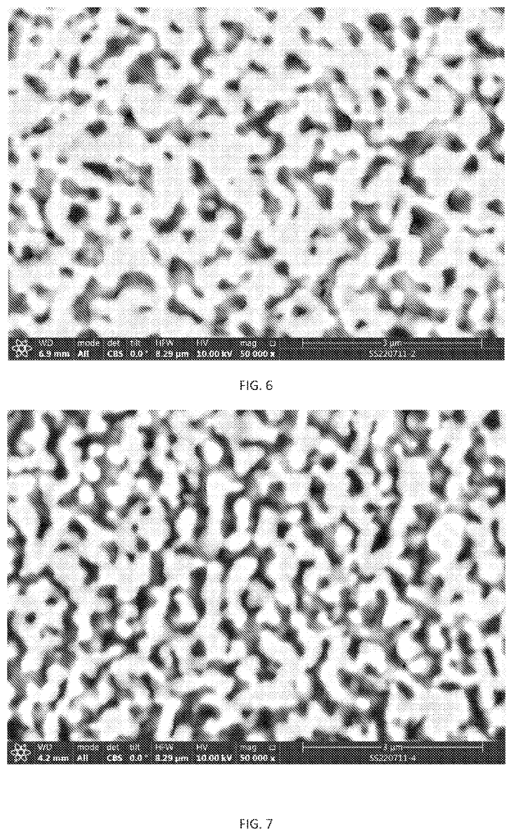

FIG. 5 shows a diagram of a thermal gasket interposed between a heat source and heat sink to establish a thermal interface. As shown, metal gasket 400 contacts heat sink 402 and is mechanically connected thereto by mechanical connectors 410. Mechanical connectors 410 extend through both heat source 404 and metal gasket 400, and further extend at least partially into heat sink 402 to establish the mechanical connection.

Processes for forming the deformable metal body are not considered to be particularly limited. In non-limiting examples, a metal nanoparticle composition may be applied to a working surface (preferably a substantially non-stick surface, optionally bearing a non-stick coating) or disposed within a mold. Suitable molds may be formed from materials such as glass, aluminum, silicon, stainless steel, nickel, or the like. Following partial consolidation of the metal nanoparticles according to the disclosure herein, a freestanding deformable metal body having a high degree of porosity may be produced. Suitable techniques for applying the metal nanoparticle composition to a working surface may include techniques such as, but not limited to, spray on, brush on, dip coating, ink jet printing, stenciling, spin-on coating, or similar application techniques. The viscosity of the metal nanoparticle composition may be tailored to support a chosen deposition technique.

Methods for forming a thermal connection between a heat source and a heat sink may comprise providing a thermal gasket of the present disclosure, placing the thermal gasket against a heat sink and applying a pressurizing load thereto (optionally through mechanically coupling the thermal gasket to the heat sink with at least one mechanical connector), and placing a heat source upon the thermal gasket upon a face thereof opposite the heat sink, such that the thermal gasket is interposed between the heat source and the heat sink. Optionally, a joining material within the nanoporosity of the thermal gasket may be squeezed out of the thermal gasket during application of the pressurizing load to aid in affixing the thermal gasket to the heat source and the heat sink. The joining material may be utilized in this regard either with or without utilization of at least one mechanical connector to promote application of the pressurizing load.

Embodiments disclosed herein include:

A. Deformable structures comprising a metal. The deformable structures comprise: a deformable metal body having a uniform nanoporosity of about 40% to about 75% by volume, the deformable metal body being freestanding and formed from a plurality of metal nanoparticles that are partially consolidated together with each other.

A1. A thermal gasket comprising the deformable structure of A, optionally containing a joining material within at least a portion of the nanoporosity.

B. Thermal interfaces. The thermal interfaces comprise: a heat source; a heat sink; and a thermal gasket comprising a deformable metal body having a uniform nanoporosity of about 40% to about 75% by volume, the deformable metal body being freestanding and formed from a plurality of metal nanoparticles that are partially consolidated together with each other; wherein the thermal gasket is interposed between and contacts the heat source and the heat sink.

C. Processes for forming a thermal interface. The processes comprise: providing a thermal gasket comprising a deformable metal body having a uniform nanoporosity of about 40% to about 75% by volume, the deformable metal body being freestanding and formed from a plurality of metal nanoparticles that are partially consolidated together with each other; placing the thermal gasket against a heat sink and applying a pressurizing load thereto; optionally, mechanically coupling the thermal gasket to the heat sink with at least one mechanical connector to establish the pressurizing load; and placing a heat source upon the thermal gasket on a face thereof opposite the heat sink, such that the thermal gasket is interposed between the heat source and the heat sink.

Embodiments A, A1, B, and C may have one or more of the following additional elements in any combination:

Element 1: wherein at least a majority of the nanoporosity comprises a plurality of open cells.

Element 2: wherein the deformable metal body comprises a metal film, a metal foil, or a metal foam.

Element 3: wherein at least one face of the deformable metal body is contoured.

Element 4: wherein the deformable metal body has a maximum thickness at a geometric center thereof, and the maximum thickness ranges from about 10 microns to about 1,000 microns.

Element 5: wherein the at least one face of the deformable metal body is dome-shaped.

Element 6: wherein the deformable metal body has a maximum thickness ranging from about 10 microns to about 1,000 microns.

Element 7: wherein the deformable metal body comprises copper and is formed from a plurality of copper nanoparticles that are partially consolidated together.

Element 8: wherein a plurality of holes extend through the deformable metal body.

Element 9: wherein a pressurizing load is applied to the thermal gasket while the thermal gasket contacts the heat sink.

Element 10: wherein the thermal gasket conforms to a surface of the heat source and the heat sink after being interposed therebetween under the pressurizing load.

Element 11: wherein the thermal gasket is mechanically coupled to the heat sink via at least one mechanical connector, optionally wherein the thermal gasket is further coupled to the heat source and the heat sink with a joining material.

Element 12: wherein the at least one mechanical connector comprises at least one of a spring-loaded push pin, a captive screw or bolt, a low-profile screw or bolt, or any combination thereof.

Element 13: wherein the at least one mechanical connector extends through the thermal gasket and at least partially into the heat sink.

Element 14: wherein the at least one mechanical connector extends through the heat source and the thermal gasket, and extends at least partially into the heat sink.

Element 15: wherein the thermal gasket is coupled to the heat source and the heat sink with a joining material.

By way of non-limiting example, exemplary combinations applicable to A, A1, B, and C include, but are not limited to, 1 and 2; 1 and 3; 1, 3, and 5; 1, 3, and 4; 1, 4, and 5; 1 and 4; 1 and 5; 1 and 6; 1 and 7; 1 and 8; 2 and 3; 2, 3, and 5; 2-4; 2 and 4; 2 and 5; 2 and 6; 2 and 7; 2 and 8; 3 and 4; 3 and 5; 3 and 7; 3 and 8; 4 and 5; 4 and 7; 4 and 8; 5 and 6; 5 and 7; 5 and 8; 6 and 7; 6 and 8; and 7 and 8. Additional exemplary combinations applicable to B and C may include any of the foregoing in further combination with one or more of 9, 10, 11, 12, 13, or 14. Further exemplary combinations applicable to B and C include, but are not limited to, 9 and 10; 9 and 11; 9-11; 9-12; 9, 11, and 12; 9, 11, and 13; 9, 11, and 14; 9, 10, 11, and 13; 9, 10, 11, and 14; 9, 10, and 15; 9, 11, and 15; 9-11 and 15; 9, 11, 14, and 15; 9, 11, 13, and 15; 9, 11, 14, and 15; 10 and 11; 10-12; 10-13; 10-12, and 14; 10, 11, and 13; 10, 11, and 14; 11 and 12; 11 and 13; 11 and 14; and 11 and 15.

To facilitate a better understanding of the present disclosure, the following examples of preferred or representative embodiments are given. In no way should the following examples be read to limit, or to define, the scope of the invention.

### EXAMPLES

### Thermal Gasket Preparation Using an Al Substrate

(Prophetic). An Al substrate (4×4 inches in size (10.16 cm×10.16 cm), and 2.15 mm thick) is prepared by machining a concave depression 2 inches wide (5.08 cm) and 3 inches (7.62 cm) long with an arc 15 microns deep and a radius of curvature of 20.8 m for the short edge and a radius of 46.87 m for the long edge. A depth of 40 microns is established at the geometric center to provide an arc radius though the geometric center of 17.57 m across the short width and an arc radius through the geometric center of 7.81 m across the long width. Using a 2 mil stencil with a 2 inch×3 inch (5.08 cm×7.62 cm) aperture, the cavity is filled with a copper nanoparticle paste formulation having a density in the range of 4.8-5.4 g/cm³ and additives having an average boiling point in the range of 220° C. Using a stainless steel squeegee at a 75 degree downward angle and at a speed of 2.67 in/sec (6.78 cm/sec), the paste is smoothed flush with the stencil surface. The stencil is removed, and the uncured part is placed in a reflow oven under nitrogen (<65 ppm oxygen content) and fused. The general profile conditions include a peak temperature of 220-230° C. and an overall duration of 5-8 min, with the conveyer belt speed being chosen based upon the oven size and number of zones. The initial heating ramp is in the 60-120° C./min range, and the overall gas flow rate is set to a minimum acceptable value. A shield may be used to prevent overly fast drying out in the beginning of the heating process. The gasket color following fusion is salmon pink. After cooling to room temperature, the copper surface is carefully polished to a smooth and flat finish to provide a flat surface having a profile above the Al substrate of around 8-12 microns. The resultant copper thermal gasket is carefully peeled off of the Al substrate for use.

Thermal Gasket Preparation Using a Stainless Steel Substrate (Prophetic). A stainless steel substrate (4×4 inches in size (10.16 cm×10.16 cm), and 2.2 mm thick) is prepared by machining a concave depression having dimensions of 1×1 inches (2.54 cm×2.54 cm) with an arc 10 micron deep and a radius of curvature of 8.0 m for both edges. A depth of 20 microns is established at the geometric center with an arc radius of 4.0 m across the geometric center and bisecting the edges. Using a 2 mil stencil having a 1×1 inches (2.54 cm×2.54 cm) aperture, the cavity is filled with a copper nanoparticle paste formulation having a density in the range of 4.8-5.4 g/cm³ and additives having an average boiling point in the range of 205° C. Using a stainless steel squeegee at a 75 degree downward angle and at a speed of 2.67 in/sec (6.78 cm/sec), the paste is smoothed flush with the stencil surface. The stencil is removed, and the uncured part is placed in a reflow oven under nitrogen (<65 ppm oxygen content) and fused. The general profile conditions include a peak temperature of 220-230° C. and an overall duration of 5-8 min, with the conveyer belt speed being chosen based upon the oven size and number of zones. The initial heating ramp is in the 60-120° C./min range, and the overall gas flow rate is set to a minimum acceptable value. A shield may be used to prevent overly fast drying out in the beginning of the heating process. The gasket color following fusion is salmon pink. After cooling to room temperature, the copper surface is carefully polished to a smooth and flat finish to provide a flat surface having a profile above the Al substrate of around 8-12 microns. The resultant copper thermal gasket is carefully peeled off of the Al substrate for use.

FIGS. 6 and 7 are SEM images of illustrative metal gaskets formed from consolidation of copper nanoparticles and having differing levels of porosity, according to one or more embodiments of the present disclosure. The porosity of the metal gasket in FIG. 6 was approximately 32% and approximately 58% for the metal gasket in FIG. 7. The interconnected pore structure is clearly visible in the higher porosity sample. In the lower porosity sample, more closed-cell pores were present in combination with the interconnected pore structure.

Unless otherwise indicated, all numbers expressing quantities of ingredients, properties such as molecular weight, reaction conditions, and so forth used in the present specification and associated claims are to be understood as being modified in all instances by the term “about.” Accordingly, unless indicated to the contrary, the numerical parameters set forth in the following specification and attached claims are approximations that may vary depending upon the desired properties sought to be obtained by the embodiments of the present invention. At the very least, and not as an attempt to limit the application of the doctrine of equivalents to the scope of the claim, each numerical parameter should at least be construed in light of the number of reported significant digits and by applying ordinary rounding techniques.

Whenever a numerical range with a lower limit and an upper limit is disclosed, any number and any included range falling within the range is specifically disclosed, including the lower limit and upper limit. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

All documents described herein are incorporated by reference herein for purposes of all jurisdictions where such practice is allowed, including any priority documents and/or testing procedures to the extent they are not inconsistent with this text. As is apparent from the foregoing general description and the specific embodiments, while forms of the disclosure have been illustrated and described, various modifications can be made without departing from the spirit and scope of the disclosure. Accordingly, it is not intended that the disclosure be limited thereby. For example, the compositions described herein may be free of any component, or composition not expressly recited or disclosed herein. Any method may lack any step not recited or disclosed herein. Likewise, the term “comprising” is considered synonymous with the term “including.” Whenever a method, composition, element or group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

One or more illustrative embodiments incorporating the features of the present disclosure are presented herein. Not all features of a physical implementation are described or shown in this application for the sake of clarity. It is understood that in the development of a physical embodiment incorporating the present disclosure, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The disclosure herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces. What is claimed is:

1. A deformable structure comprising:
a deformable metal body having a uniform nanoporosity of about 40% to about 75% by volume, the deformable metal body being freestanding and formed from a plurality of metal nanoparticles that are partially consolidated together with each other.

2. The deformable structure of claim 1, wherein at least a majority of the nanoporosity comprises a plurality of open cells.

3. The deformable structure of claim 1, wherein the deformable metal body comprises a metal film, a metal foil, or a metal foam.

4. The deformable structure of claim 1, wherein at least one face of the deformable metal body is contoured.

5. (canceled)

6. The deformable structure of claim 4, wherein the at least one face of the deformable metal body is dome-shaped.

7. The deformable structure of claim 1, wherein the deformable metal body has a maximum thickness ranging from about 10 microns to about 1,000 microns.

8. The deformable structure of claim 1, wherein the deformable metal body comprises copper and is formed from a plurality of copper nanoparticles that are partially consolidated together.

9. A thermal gasket comprising the deformable structure of claim 1, optionally where a plurality of holes extend through the deformable metal body.

10. (canceled)

11. The thermal gasket of claim 9, wherein at least one face of the deformable metal body is contoured.

12. The thermal gasket of claim 9, further comprising:
a joining material contained within at least a portion of the nanoporosity.

13. A thermal interface comprising:
a heat source;
a heat sink; and
a thermal gasket comprising a deformable metal body having a uniform nanoporosity of about 40% to about 75% by volume, the deformable metal body being freestanding and formed from a plurality of metal nanoparticles that are partially consolidated together with each other;
wherein the thermal gasket is interposed between and contacts the heat source and the heat sink; and
optionally, wherein the thermal gasket is mechanically coupled to the heat sink via at least one mechanical connector.

14. The thermal interface of claim 13, wherein at least a majority of the nanoporosity comprises a plurality of open cells.

15. The thermal interface of claim 13, wherein a pressurizing load is applied to the thermal gasket while the thermal gasket contacts the heat sink.

16. The thermal interface of claim 15, wherein the thermal gasket conforms to a surface of the heat source and the heat sink after being interposed therebetween under the pressurizing load.

17. (canceled)

18. (canceled)

19. The thermal interface of claim 13, wherein the at least one mechanical connector is present and comprises at least one of a spring-loaded push pin, a captive screw or bolt, a low-profile screw or bolt, or any combination thereof.

20. The thermal interface of claim 13, wherein the at least one mechanical connector is present and extends through the thermal gasket and at least partially into the heat sink.

21. The thermal interface of claim 13, wherein the at least one mechanical connector is present and extends through the heat source and the thermal gasket, and extends at least partially into the heat sink.

22. The thermal interface of claim 13, wherein the thermal gasket is coupled to the heat source and the heat sink with a joining material.

23. A process comprising:
providing a thermal gasket comprising a deformable metal body having a uniform nanoporosity of about 40% to about 75% by volume, the deformable metal body being freestanding and formed from a plurality of metal nanoparticles that are partially consolidated together with each other;
placing the thermal gasket against a heat sink and applying a pressurizing load thereto;
optionally, mechanically coupling the thermal gasket to the heat sink with at least one mechanical connector to establish the pressurizing load; and
placing a heat source upon the thermal gasket on a face thereof opposite the heat sink, such that the thermal gasket is interposed between the heat source and the heat sink.

24. The process of claim 23, wherein at least a majority of the nanoporosity comprises a plurality of open cells.

25. The process of claim 23, wherein the at least one mechanical connector comprises at least one of a spring-loaded push pin, a captive screw or bolt, a low-profile screw or bolt, or any combination thereof.

26. The process of claim 23, wherein the at least one mechanical connector extends through the thermal gasket and at least partially into the heat sink.

27. The process of claim 23, wherein the at least one mechanical connector extends through the heat source and the thermal gasket, and extends at least partially into the heat sink.
